(19) United States
(12) Patent Application Publication
(10) Pub. No.: US 2008/0271915 A1
(43) Pub. Date: Nov. 6, 2008

(54) METHOD FOR MAKING A CIRCUIT BOARD AND MULTI-LAYER SUBSTRATE WITH PLATED THROUGH HOLES

(75) Inventor: Chien Hao WANG, Hsinchu County (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., KAOHSIUNG (TW)

(21) Appl. No.: 11/941,787

(22) Filed: Nov. 16, 2007

(30) Foreign Application Priority Data
Nov. 17, 2006 (TW) 095142735

(51) Int. Cl. H01R 12/04; H05K 3/36

(52) U.S. Cl. 174/266; 29/830

(57) ABSTRACT

A method for making a circuit board includes the following steps. At least two substrates are provided, wherein each substrate includes two surfaces, two circuit layers respective formed on the two surfaces and at least a via passing through the two surfaces. A metal layer is formed on the side wall of the via, wherein the metal layer electrically connects two circuit layers on the two surfaces of each substrate to each other. An insulating film is at least formed on the surface of the metal layer by an electrophoretic deposition process. Vias of two substrates are aligned with each other and two substrates are laminated to each other, so as to form a multi-layer substrate. Another metal layer is formed on the insulating film, wherein each metal layer is an independent electrical channel.

### CROSS REFERENCE TO RELATED APPLICATION

This application claims the priority benefit of Taiwan Patent Application Serial Number 095142735, filed Nov. 17, 2006, the full disclosure of which is incorporated herein by reference.

### BACKGROUND OF THE INVENTION

1. Field of the Invention

The present invention generally relates to a method for making a circuit board, and more particularly to a method for making a circuit board by using an electrophoretic deposition process.

2. Description of the Related Art

As the technology and life quality are gradually advanced, the consume requests electronic products not only to have good multifunction but also to be light, thin, short and small. Thus, the higher the integration of the electronic product is, the better the multifunction of the electronic product is.

In order to meet the above-mentioned requirement, a circuit board which is in the electronic product and equipped with electronic components is gradually developed from the build-up substrate having one circuit layer to the build-up substrate having two, four, eight and even above ten circuit layers. Thus, the electronic components are assembled on the circuit board in higher density so as to decrease the volume of the electronic product.

However, the build-up substrate having a plurality of circuit layers necessarily includes plated through holes (PTH), blind vias, buried vias, or various vias for electrically connecting two of the circuit layers to each other, generally. Thus, the technology for making the vias is quiet important.

Referring to FIGS. 1A to 1C, they depict a conventional method for making plated through holes in the circuit board. Referring to FIG. 1A, two circuit layers 11 are formed on two sides (upper and lower sides) of a substrate 10 respectively, and at least one via 12 passes through the two sides of the substrate 10. Then, a metal layer 13 is formed on a side wall of the via 12, and the metal layer 13 electrically connects the two circuit layers 11 on the two sides of the substrate 10 to each other so as to be an electrical channel between the two circuit layers 11 on the two sides. The above-mentioned via 12 is formed by using a mechanical drilling process or a laser drilling process.

Referring to FIG. 1B, the via 12 is filled with an insulating material 14 in order to make an insulating layer on the surface of the metal layer 13. Referring to FIG. 1C, after the via 12 has been filled with an insulating material 14, a part of the insulating material 14 is removed by using another mechanical drilling process or another laser drilling process, and the rest of the insulating material 14 (i.e. the insulating layer 16) is adjacent to the metal layer 13.

It is noted that the diameter of drilling for removing the insulating material 14 must be less than that for making the via 12, thereby keeping the rest of the insulating material 14 so as to form the insulating layer 16 on the surface of the metal layer 13.

After the insulating layer 16 has been formed on the surface of the metal layer 13, the substrate 10 can be laminated to another circuit board. Then, another metal layer is formed on the insulating film, and the circuit layer of the substrate 10 can be electrically connected to the circuit layer of another circuit board.

According to the above-mentioned making process, the drilling step for removing the insulating material 14 is substantially difficult. In the drilling step, the diameter of drilling being less than that of the via 12 is used for removing the insulating material 14 in the via 12. The accuracy and precision of positioned drilling must be stably controlled, otherwise it is easy that the thickness of the insulating layer 16 (shown in FIG. 1C) is not uniform and further the insulating layer 16 is useless. Thus, the above-mentioned method for making the insulating layer 16 is complex so as not to effectively increase the making yield.

Accordingly, there exists a need for a method for making a circuit board capable of solving the above-mentioned problems.

### SUMMARY OF THE INVENTION

It is an object of the present invention to provide a method for making a circuit board capable of decreasing the number of plated through holes and further narrowing the size of circuit board.

It is another object of the present invention to provide a method for making a circuit board capable of increasing the density of circuit layout, having good property of circuit and reducing the cross-talk effect by properly arranging insulating film of plated through hole and circuit layout.

In order to achieve the foregoing object, the present invention provides a method for making a circuit board comprising the following steps. A first substrate is provided and includes a first surface, a second surface opposite to the first surface, a first circuit layer formed on the first surface, a second circuit layer formed on the second surface, at least one first via passing through the first surface and the second surface, and a first metal layer formed on a side wall of the first via for electrically connecting the first circuit layer to the second circuit layer.

A second substrate is provided and includes a third surface, a fourth surface opposite to the third surface, a third circuit layer formed on the third surface, a fourth circuit layer formed on the fourth surface, at least one second via passing through the third surface and the fourth surface, and a second metal layer formed on a side wall of the second via for electrically connecting the third circuit layer to the fourth circuit layer.

The first via is aligned with the second via, and the first substrate is laminated to the second substrate so as to form a multi-layer substrate. An insulating film is formed on the first and second metal layers by using an electrophoretic deposition process. Finally, a third metal layer is formed on the insulating film for electrically connecting the first circuit layer to the fourth circuit layer.

The present invention further provides a method for making a circuit board comprising the following steps. A first substrate is provided and includes a first surface, a second surface opposite to the first surface, a first circuit layer formed on the first surface, a second circuit layer formed on the second surface, at least one first via passing through the first surface and the second surface, and a first metal layer formed on a side wall of the first via for electrically connecting the first circuit layer to the second circuit layer.

A second substrate is provided and includes a third surface, a fourth surface opposite to the third surface, a third circuit layer formed on the third surface, a fourth circuit layer formed on the fourth surface, at least one second via passing through the third surface and the fourth surface, and a second metal layer formed on a side wall of the second via for electrically connecting the third circuit layer to the fourth circuit layer.

An insulating film is at least formed on the first metal layer by using an electrophoretic deposition process. The first via is aligned with the second via, and the first substrate is laminated to the second substrate so as to form a multi-layer substrate. Finally, a third metal layer is formed on the insulating film for electrically connecting the first circuit layer to the fourth circuit layer.

The present invention further provides a multi-layer substrate with plated through holes including a first substrate, a first metal layer, a second substrate, a second metal layer, an insulating film and a third metal layer. The first substrate includes a first surface, a second surface opposite to the first surface, a first circuit layer formed on the first surface, a second circuit layer formed on the second surface, and at least one first via passing through the first surface and the second surface. The first metal layer is formed on a side wall of the first via for electrically connecting the first circuit layer to the second circuit layer.

The second substrate includes a third surface, a fourth surface opposite to the third surface, a third circuit layer formed on the third surface, a fourth circuit layer formed on the fourth surface, and at least one second via communicated with the first via and passing through the third surface and the fourth surface. The second metal layer is formed on a side wall of the second via for electrically connecting the third circuit layer to the fourth circuit layer. The insulating film is at least formed on the first metal layer by using an electrophoretic deposition process. The third metal layer is formed on the insulating film.

The foregoing, as well as additional objects, features and advantages of the invention will be more apparent from the following detailed description, which proceeds with reference to the accompanying drawings.

### BRIEF DESCRIPTION OF THE DRAWINGS

FIGS. 1A to 1C are cross-sectional schematic views of a method for making a circuit board in the prior art.

FIGS. 2A to 2F are cross-sectional schematic views of a method for making a circuit board according to the first embodiment of the present invention.

FIGS. 3A to 3C are cross-sectional schematic views of a method for making a circuit board according to the second embodiment of the present invention, showing the steps different from those of the first embodiment.

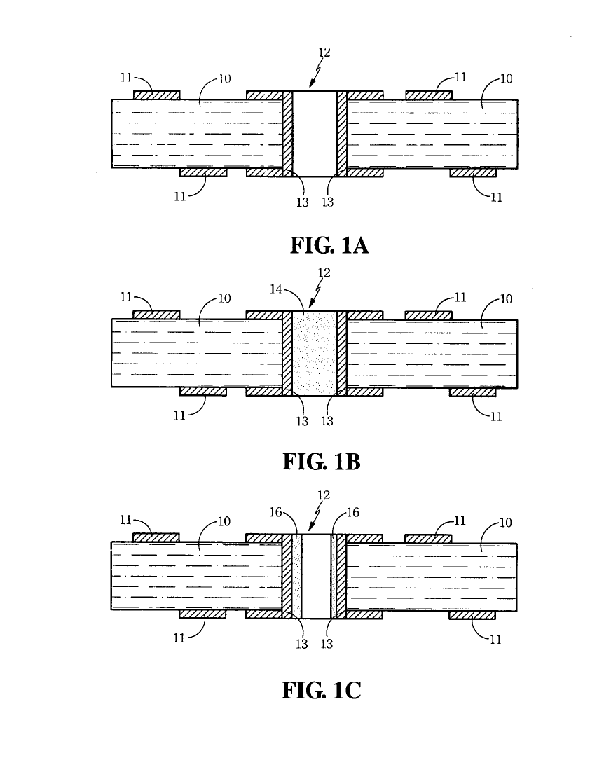

### DETAILED DESCRIPTION OF THE PREFERRED EMBODIMENT

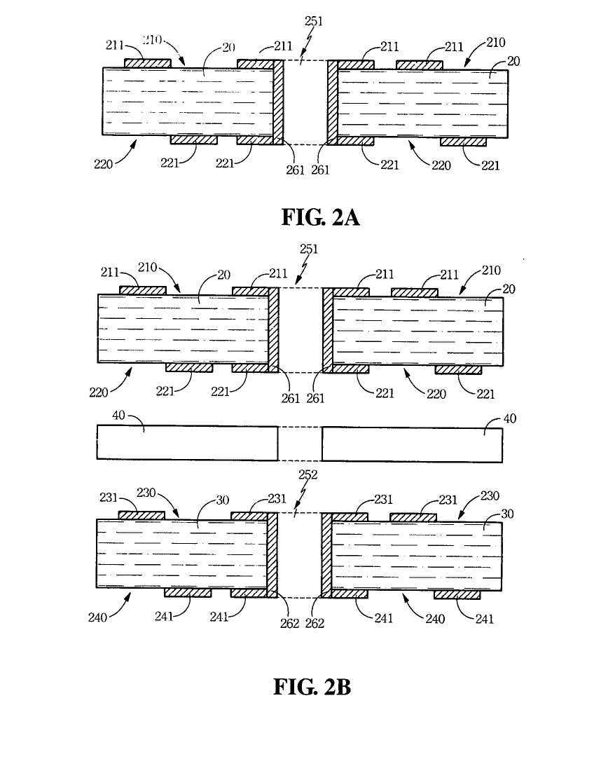

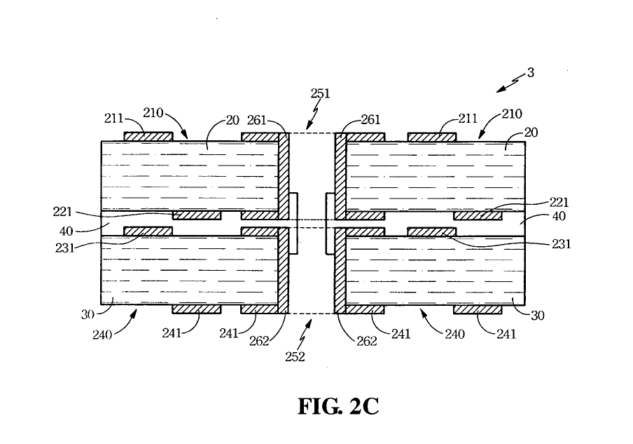

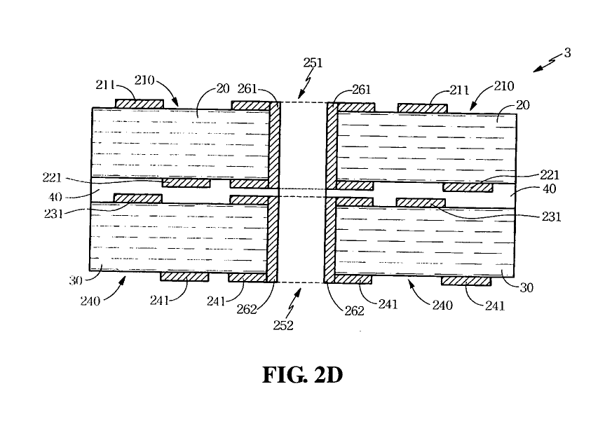

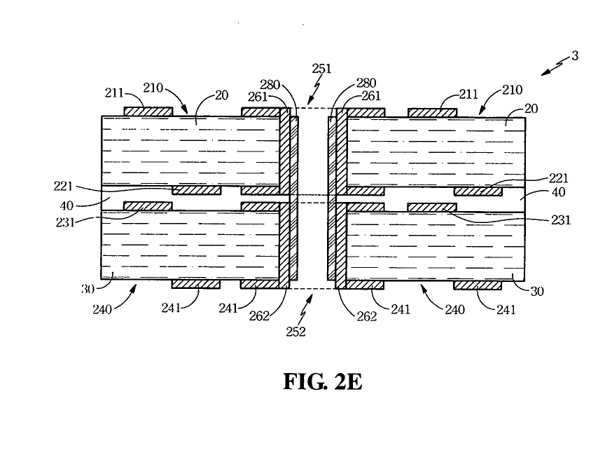

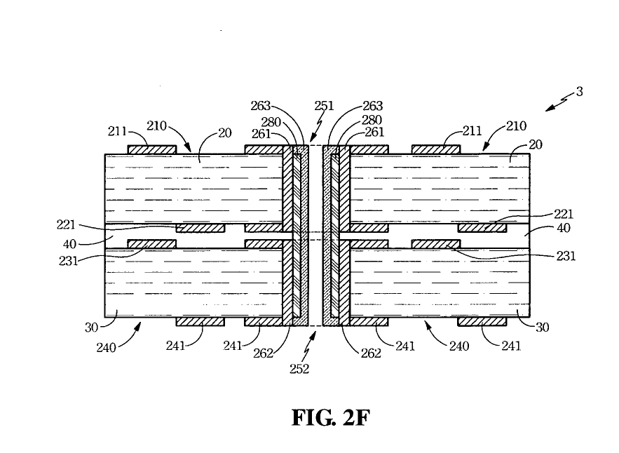

Referring to FIGS. 2A to 2F, they depict a method for making a circuit board according to the first embodiment of the present invention. Referring to FIG. 2A, a first substrate 20 is provided and includes a first circuit layer 211 formed on a first surface 210 and a second circuit layer 221 formed on a second surface 220, wherein the second surface 220 is opposite to the first surface 210. The first surface 210 and the second surface 220 are the upper and lower surfaces of first substrate 20 respectively.

In addition, at least one first via 251 passes through the first surface 210 and the second surface 220, and a first metal layer 261 is formed on a side wall of the first via 251 for electrically connecting the first circuit layer 211 to the second circuit layer 221. In other words, the first metal layer 261 provides an electrical channel between the first circuit layer 211 and the second circuit layer 221. The first via 251 is formed by using a mechanical drilling process or a laser drilling process, and the first metal layer 261 is formed by using an electroplating process.

Referring to FIG. 2B, a second substrate 30 is further provided according to the present invention. The second substrate 30 includes a third circuit layer 231 formed on a third surface 230 and a fourth circuit layer 241 formed on a fourth surface 240, wherein the fourth surface 220 is opposite to the third surface 210. The third surface 230 and the fourth surface 240 are the upper and lower surfaces of second substrate 30 respectively.

In addition, at least one second via 252 passes through the third surface 230 and the fourth surface 240, and a second metal layer 262 is formed on a side wall of the second via 252 for electrically connecting the third circuit layer 231 to the fourth circuit layer 241. In other words, the second metal layer 262 provides an electrical channel between the third circuit layer 231 and the fourth circuit layer 241. The second via 252 is formed by using a mechanical drilling process or a laser drilling process, and the second metal layer 262 is formed by using an electroplating process.

Referring to FIG. 2B again, after circuit layers and metal layers of the first and second substrates 20, 30 have been completed, the first via 251 can be aligned with the second via 252 and the first substrate 20 can be laminated to the second substrate 30 so as to form a multi-layer substrate 3. A dielectric layer 40 is sandwiched in between the first substrate 20 and the second substrate 30, i.e. the first substrate 20 and the second substrate 30 are laminated on two sides of the dielectric layer 40.

In a preferred embodiment, the above-mentioned substrates can be copper-foil-laminated substrates. Circuit layers on the upper and lower surfaces of the substrates are formed by photolithographing and etching copper foils on the copper-foil-laminated substrates.

Referring to FIG. 2C, it is easy that some dielectric materials of the dielectric layer 40 is spilt between the first via 251 and the second via 252 when the first substrate 20 is laminated to the second substrate 30. Furthermore, there are also some dielectric matters or impure matters to be attached to the substrates in the process for making the substrate.

Thus, it is necessary to use a cleaning process for removing the above-mentioned impure matters, dielectric matters or redundant dielectric materials spilt between the first via 251 and the second via 252 during laminating, whereby the surfaces of the first and second metal layers 261, 262 are uniform and cleaned. The multi-layer substrate 3, shown in FIG. 2D, has been cleaned by the cleaning process. The clean process includes a plasma cleaning process.

Referring to FIG. 2E, after the multi-layer substrate 3 has been cleaned by the cleaning process, the multi-layer substrate 3 is processed by an electrophoretic deposition process, whereby an insulating film 280 is formed on the surfaces of the first and second metal layers 261, 262 by using the electrophoretic deposition process.

The electrophoretic deposition process includes following steps: polymer micelles are deposited on the surfaces of the first and second metal layers 261, 262 by using a depositing step; and then the polymer micelles are polymerized to the insulating film 280 by using a thermal treatment process.

More detailed, the polymer micelles are scattered in the solution, and then the polymer micelles are electrophoretically deposited on the surfaces of the first and second metal layers 261, 262 by the action of electric field. The polymer micelles in the solution are a kind of polymers which are not polymerized and are still colloidal when the polymer micelles are deposited on the surfaces of the first and second metal layers 261, 262. Thus, it is necessary to use the thermal treatment process necessarily including a dehydration step and a cyclization step for polymerizing the polymer micelles to be necessary type of polymer.

The polymer micelles includes silicone-inorganic particles and polymer precursors, wherein the polymer precursors are selected from the group consisting of Polyimide (PI) resin and derivative thereof, epoxy resin and derivative thereof, polymer resin including halogen, flameproof polymer resin including phosphorus (P), silicon (Si) and sulfur (S).

It is noted that the electrophoretic deposition process has the advantage of depositing the insulating film on the surfaces of the metal layer rather than the whole substrate. Also, the thickness of the insulating film can be controlled by the current, voltage or time of deposition so as to be even lower than 10 micrometers. Thus, the thickness of the insulating film of the present invention is much thinner than that in the prior art.

The insulating film 280 is only formed on the surfaces of the first and second metal layers 261, 262. Thus, before the electrophoretic deposition process a mask (not shown) is firstly provided on the first circuit layer 211 and the fourth circuit layer 241 of the multi-layer substrate 3 so as to avoid depositing the insulating film on the first circuit layer 211 and the fourth circuit layer 241. The mask can be a dry film.

Referring to FIG. 2F, after the insulating film 280 has been formed on the surfaces of the first and second metal layers 261, 262, a third metal layer 263 is formed on the insulating film 280. The third metal layer 263 is formed by using an electroless plating process for connecting the first circuit layer 211 to the fourth circuit layer 241.

Thus, a plated through hole can be constituted of the above-mentioned first via 251, second via 252, first metal layer 261, second metal layer 262, insulating film 280 and third metal layer 263.

In this embodiment, the multi-layer substrate 3 can have inner and outer circuit channels because of the arrangement of plated through holes and insulating film 280 thereof. The inner circuit channel is that the first circuit layer 211 is electrically connected to the second circuit layer 221 by means of the first metal layer 261, and the third circuit layer 231 is electrically connected to the fourth circuit layer 241 by means of the second metal layer 262. The outer circuit channel is that the first circuit layer 211 is electrically connected to the fourth circuit layer 241 by means of the third metal layer 263. Thus, each metal layer in the plated through hole can be an independent electrical channel.

In the second embodiment, the electrical channels between two of the circuit layers further has the advantages of flexibility and change the processes and steps by adjusting the processes and steps in the first embodiment.

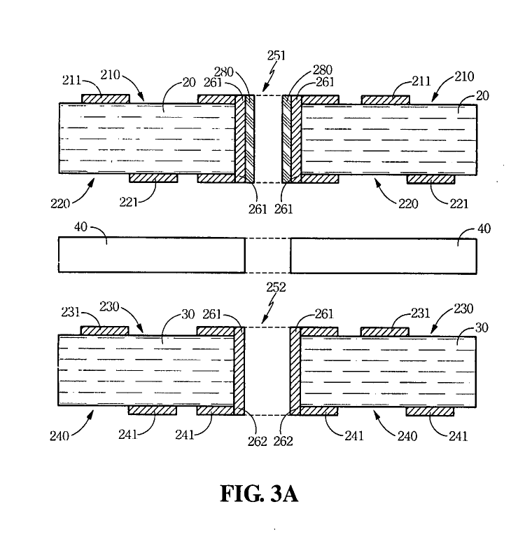

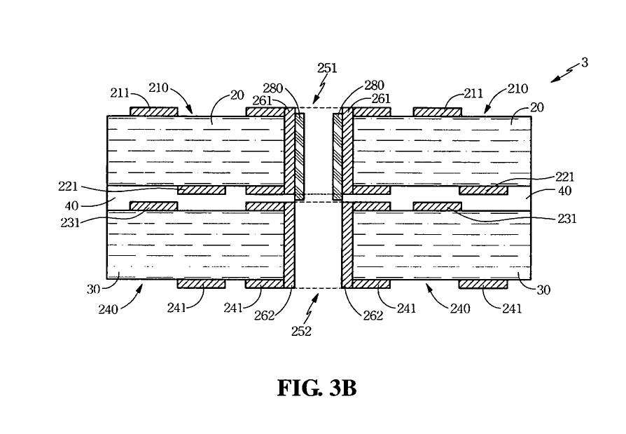

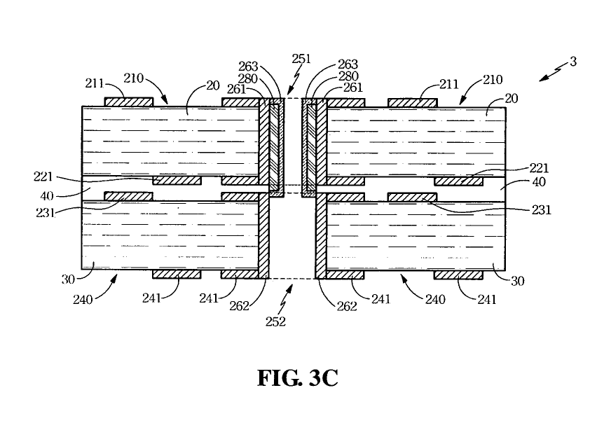

Referring to FIG. 3A, first and second substrates 20, 30 are provided, and circuit layers 211, 221, 231, 241 and metal layers 261, 262 are formed. Then, an insulating film 280 is formed on the surfaces of the first metal layer 261 by using the electrophoretic deposition process.

The electrophoretic deposition process includes following steps: polymer micelles are deposited on the surfaces of the first metal layer 261 by using a depositing process; and then the polymer micelles are polymerized to the insulating film 280 by using a thermal treatment process. The depositing and thermal treatment process in the second embodiment substantially similar to those in the first embodiment, wherein the difference between the first and second embodiments is that the first substrate 20 in the second embodiment is only processed by the electrophoretic deposition process.

However, the insulating film 280 is only formed on the surfaces of the first metal layer 261. Thus, before the electrophoretic deposition process a mask (not shown) is firstly provided on the first circuit layer 211 and the second circuit layer 221 of the first substrate 20 so as to avoid depositing the insulating film on the first circuit layer 211 and the second circuit layer 221. The mask can be a dry film.

After the insulating film 280 has been formed, the first via 251 can be aligned with the second via 252 and the first substrate 20 can be laminated to the second substrate 30 so as to form a multi-layer substrate 3. A dielectric layer 40 is sandwiched in between the first substrate 20 and the second substrate 30, i.e. the first substrate 20 and the second substrate 30 are laminated on two sides of the dielectric layer 40.

Referring to FIG. 3B, it depicts a multi-layer substrate 3. However, there are also some dielectric matters or impure matters to happen in the process for making the multi-layer substrate 3. Thus, it is necessary to use a cleaning process for removing the above-mentioned impure matters, dielectric matters or redundant dielectric materials as the first embodiment.

Referring to FIG. 3C, after a cleaning process a third metal layer 263 is formed on the insulating film 280. The third metal layer 263 is formed by an electroless plating process and electrically connects the first circuit layer 211 to the third circuit layer 231.

In this embodiment, the multi-layer substrate 3 can have inner and outer circuit channels because of the arrangement of plated through holes and insulating film 280 thereof. The inner circuit channel is that the first circuit layer 211 is electrically connected to the second circuit layer 221 by means of the first metal layer 261, and the third circuit layer 231 is electrically connected to the fourth circuit layer 241 by means of the second metal layer 262. The outer circuit channel is that the first circuit layer 211 is electrically connected to the third circuit layer 231 by means of the third metal layer 263. Thus, each metal layer in the plated through hole can be an independent electrical channel.

In addition, the circuit layer 30 in the second embodiment can be processed by the electrophoretic deposition process if necessary, whereby the insulating film 280 is also formed on the second metal layer 262. Then, the third metal layer 263 formed on the insulating film 280 can electrically connects the first circuit layer 211 to the fourth circuit layer 241.

FIGS. 2F and 3C respectively show the multi-layer substrate 3 with plated through holes of the present invention. The multi-layer substrate 3 includes the first substrate 20, the first metal layer 261, the second substrate 30, the second metal layer 262, the insulating film 280 and the third metal layer 263.

The first substrate 20 includes the first circuit layer 211 formed on the first surface 210 and the second circuit layer 221 formed on the second surface 220, wherein the second surface 220 is opposite to the first surface 210. The first substrate 20 further includes at least one first via 251 passing through the first surface 210 and the second surface 220. The first metal layer 261 is formed on the side wall of the first via 251 for electrically connecting the first circuit layer 211 to the second circuit layer 221.

The second substrate 30 includes the third circuit layer 231 formed on the third surface 230 and the fourth circuit layer 241 formed on the fourth surface 240, wherein the fourth surface 220 is opposite to the third surface 210. The second substrate 30 further includes at least one second via 252 passing through the third surface 230 and the fourth surface 240 and communicated with the first via 251. The second metal layer 262 is formed on the side wall of the second via 252 for electrically connecting the third circuit layer 231 to the fourth circuit layer 241. The insulating film 280 is at least formed on the surfaces of the first metal layer 261 by using the electrophoretic deposition process. Finally, the third metal layer 263 is formed on the insulating film 280.

The first and second vias 251, 252 are formed by using the mechanical drilling process or the laser drilling process. The first and second metal layers 261, 262 are formed by using the electroplating process. The third metal layer 263 is formed by using the electroless plating process. The first substrate 20 and the second substrate 30 are laminated on two sides of the dielectric layer 40.

It is noted that the outer electric channel can be changed by adjusting the covering area of the insulating film 280 on the first and second metal layers 261, 262 if necessary. For example, the third metal layer 263 becomes the electric channel from the first circuit layer 211 to the third circuit layer 231 when the insulating film 280 is only formed on the first metal layer 261. The third metal layer 263 becomes the electric channel from the first circuit layer 211 to the fourth circuit layer 241 when the insulating film 280 is formed on the first and second metal layers 261, 262.

In conclusion, the method for making the circuit board of the present invention provides the multi-layer substrate 3 with plated through holes having the advantages as follows:
1. The multi-layer substrate 3 can have inner and outer circuit channels which all are independent by arranging plated through holes and insulating film 280 thereof. Thus, circuit channels in the plated through hole of the present invention is more than those in the conventional plated through hole, thereby increasing the density of circuit layout, decreasing the number of plated through holes and narrowing the size of circuit board.
2. The arrangement of insulating film 280 and circuit layout can provide good property of circuit and reduce the cross-talk effect.
3. The third metal layer between circuit layers can be adjusted by arranging insulating film 280, whereby the circuit layout further has the advantages of flexibility and change.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A method for making a circuit board comprising the following steps of:
providing a first substrate including a first surface, a second surface opposite to the first surface, a first circuit layer formed on the first surface, a second circuit layer formed on the second surface, at least one first via passing through the first surface and the second surface, and a first metal layer formed on a side wall of the first via for electrically connecting the first circuit layer to the second circuit layer;
providing a second substrate including a third surface, a fourth surface opposite to the third surface, a third circuit layer formed on the third surface, a fourth circuit layer formed on the fourth surface, at least one second via passing through the third surface and the fourth surface, and a second metal layer formed on a side wall of the second via for electrically connecting the third circuit layer to the fourth circuit layer;
aligning the first via with the second via, and laminating the first substrate to the second substrate so as to form a multi-layer substrate, wherein the first substrate and the second substrate are laminated on two sides of a dielectric layer;
forming an insulating film on the first and second metal layers by using an electrophoretic deposition process; and
forming a third metal layer on the insulating film for electrically connecting the first circuit layer to the fourth circuit layer.

2. The method as claimed in claim 1, wherein the first and second metal layers are formed by using an electroplating process.

3. The method as claimed in claim 1, wherein the third metal layer is formed by using an electroless plating process.

4. The method as claimed in claim 1, further comprising the following step of:
providing a cleaning process for removing the above-mentioned impure matters, dielectric matters or redundant dielectric materials spilt between the first via and the second via during laminating before the step of forming an insulating film on the first and second metal layers by using an electrophoretic deposition process.

5. The method as claimed in claim 1, further comprising the following step of:
providing a mask on the first circuit layer and the fourth circuit layer of the multi-layer substrate before the step of forming an insulating film on the first and second metal layers by using an electrophoretic deposition process.

6. The method as claimed in claim 1, wherein the step of forming an insulating film on the first and second metal layers by using an electrophoretic deposition process comprising the following steps of:
depositing polymer micelles on the surfaces of the first and second metal layers; and
polymerizing the polymer micelles to the insulating film by using a thermal treatment process.

7. The method as claimed in claim 6, wherein the thermal treatment process includes a dehydration step and a cyclization step.

8. A method for making a circuit board comprising the following steps of:
providing a first substrate including a first surface, a second surface opposite to the first surface, a first circuit layer formed on the first surface, a second circuit layer formed on the second surface, at least one first via passing through the first surface and the second surface, and a first metal layer formed on a side wall of the first via for electrically connecting the first circuit layer to the second circuit layer;
providing a second substrate including a third surface, a fourth surface opposite to the third surface, a third circuit layer formed on the third surface, a fourth circuit layer formed on the fourth surface, at least one second via passing through the third surface and the fourth surface, and a second metal layer formed on a side wall of the second via for electrically connecting the third circuit layer to the fourth circuit layer;
forming an insulating film on the first metal layers by using an electrophoretic deposition process;
aligning the first via with the second via, and laminating the first substrate to the second substrate so as to form a multi-layer substrate, wherein the first substrate and the second substrate are laminated on two sides of a dielectric layer; and
forming a third metal layer on the insulating film.

9. The method as claimed in claim 8, further comprising the following step of:
providing a cleaning process for removing the above-mentioned impure matters, dielectric matters or redundant dielectric materials spilt between the first via and the second via during laminating before the step of forming a third metal layer on the insulating film.

10. The method as claimed in claim 8, further comprising the following step of:
providing a mask on the first circuit layer and the fourth circuit layer of the multi-layer substrate before the step of forming a third metal layer on the insulating film.

11. The method as claimed in claim 8, wherein the step of forming an insulating film on the first metal layer by using an electrophoretic deposition process comprising the following steps of:
depositing polymer micelles on the surfaces of the first and second metal layers; and
polymerizing the polymer micelles to the insulating film by using a thermal treatment process.

12. The method as claimed in claim 11, wherein the thermal treatment process includes a dehydration step and a cyclization step.

13. The method as claimed in claim 8, wherein the third metal layer electrically connects the first circuit layer to the third circuit layer.

14. The method as claimed in claim 8, wherein the third metal layer electrically connects the first circuit layer to the fourth circuit layer.

15. A multi-layer substrate with plated through holes comprising:
a first substrate including a first surface, a second surface opposite to the first surface, a first circuit layer formed on the first surface, a second circuit layer formed on the second surface, and at least one first via passing through the first surface and the second surface;
a first metal layer formed on a side wall of the first via for electrically connecting the first circuit layer to the second circuit layer;
a second substrate including a third surface, a fourth surface opposite to the third surface, a third circuit layer formed on the third surface, a fourth circuit layer formed on the fourth surface, and at least one second via communicated with the first via and passing through the third surface and the fourth surface;
a second metal layer formed on a side wall of the second via for electrically connecting the third circuit layer to the fourth circuit layer;
a dielectric layer having two sides, wherein the first substrate and the second substrate are laminated on the two sides of the dielectric layer;
an electrophoretic deposited insulating film formed on the first metal layer; and
a third metal layer formed on the insulating film.

16. The multi-layer substrate as claimed in claim 15, wherein the first and second metal layers are electroplated layers.

17. The multi-layer substrate as claimed in claim 15, wherein the third metal layer is electroless plated layer.

18. The multi-layer substrate as claimed in claim 15, wherein the third metal layer electrically connects the first circuit layer to the third circuit layer.

19. The multi-layer substrate as claimed in claim 15, wherein the insulating film is formed on the first and second metal layers.

20. The multi-layer substrate as claimed in claim 19, wherein the third metal layer electrically connects the first circuit layer to the fourth circuit layer.
